(19) United States
(12) Patent Application Publication
(10) Pub. No.: US 2024/0096926 A1
(43) Pub. Date: Mar. 21, 2024

(54) MOUNTING STRUCTURE FOR CHIP COMPONENT

(71) Applicant: KOA CORPORATION, Ina-shi, Nagano (JP)

(72) Inventor: Yasushi AKAHANE, Ina-shi (JP)

(73) Assignee: KOA CORPORATION, Ina-shi, Nagano (JP)

(21) Appl. No.: 18/276,215

(22) PCT Filed: Feb. 24, 2022
(86) PCT No.: PCT/JP2022/007577

§ 371 Date: Aug. 7, 2023

(30) Foreign Application Priority Data
Mar. 12, 2021 (JP) 2021-040509

(51) Int. Cl. H01C 1/142; H01C 7/00; H01L 23/13

(52) U.S. Cl. CPC H01L 28/20; H01C 1/142; H01C 7/003; H01L 23/13

(57) ABSTRACT

Provided is a mounting structure for a chip component having high thermal shock resistance. In amounting structure for a chip resistor 1 according to the present invention, a separation distance L1 between a pair of back surface electrodes 3 formed on an insulating substrate 2 of a chip resistor 20 is set to be shorter than a separation distance L2 between a pair of lands 31 provided on a circuit board 30. Each of the back surface electrodes 3 is formed with a thick portion (first electrode portion 3a), and an external electrode 9 deposited on the back surface electrode 3 is connected on the corresponding land 31 via solder 32 with a top portion of the thick portion made positioned directly above an inner end of the land 31.

### TECHNICAL FIELD

The present invention relates to a surface mount chip component to be soldered on lands of a circuit board.

### BACKGROUND ART

A chip resistor, which is an exemplary chip component, commonly includes a rectangular parallelepiped insulating substrate, a pair of top surface electrodes provided with a predetermined space interposed therebetween on the main (front) surface of the insulating substrate, a resistor provided so as to bridge between the pair of top surface electrodes, a protective layer for covering the resistor, a pair of back surface electrodes provided with a predetermined space interposed therebetween on the back surface of the insulating substrate, a pair of end face electrodes formed on both end faces of the insulating substrate, respectively, so as to bridge the top surface electrodes and the back surface electrodes, a pair of external electrodes formed by plating on the external surfaces of these end face electrodes, and the like.

The chip resistor having the structure as described above is surface-mounted with the back surface electrodes being placed on the lands provided on the circuit board and soldered. In the state where the chip resistor is surface-mounted as described above, when the thermal environment of the chip resistor repeatedly changes (hereinafter, referred to as “thermal shock”), a solder joint portion is easily damaged by the thermal stress, which may cause cracks to form. In the worst case, formation of cracks in the solder joint portion caused by the thermal shock may lead to conduction failure since the solder joint portion is a portion where the back surface electrodes of the chip resistor and the lands of the circuit board are electrically and mechanically connected.

In this regard, conventionally, as described in Patent Literature 1, a chip resistor of which the back surface electrodes each includes the first electrode layer made of sintered silver and a second electrode layer made of sintered silver and laminated at a position off from the edge portions of the first electrode layer has been known. This chip resistor is surface-mounted by soldering and joining the external electrodes that cover the back surface electrodes having the structure described above. In such a conventional chip resistor, steps are formed in portions extending from the side faces of the second electrode layer to the surface of the first electrode layer, and the step portions corresponding to these steps are also formed in the external electrode. Thus, the thickness of the solder joint portion increases by these step portions, whereby the thermal stress caused by the thermal shock can be relaxed using the flexibility of the solder.

### CITATION LIST

### Patent Literature

Patent Literature 1: JP-A-2013-74044

### SUMMARY OF INVENTION

### Technical Problem

However, the mounting structure for the chip resistor as described in Patent Literature 1 may cause problems in recent trends in the automotive market, which demands further improvement of thermal shock resistance for responding to the needs of the longer service life and maintenance-free products. For example, when the chip resistor is mounted using lead-free solder called high-strength solder, a joint portion becomes rigid due to its material. This may result in a risk that the thermal stress caused by the thermal shock is transmitted to the back surface electrodes without being absorbed by the solder, which may cause the damages in the solder joint portion (solder crack) and peeling off of the back surface electrodes (delamination).

The present invention has been made in view of the circumstances of the prior art as described above, and an object of the present invention is to provide a mounting structure for a chip component having high thermal shock resistance.

### Solution to Problem

In order to achieve the object above, a chip component according to the present invention is provided with a pair of back surface electrodes formed at both ends, respectively, in a longitudinal direction of a back surface of a rectangular parallelepiped insulating substrate, and end surface electrodes formed at the both ends, respectively, in the longitudinal direction of the insulating substrate and connected to the back surface electrodes, respectively, the chip component being mounted on a pair of lands provided on a circuit board with the pair of back surface electrodes facing downward, and the end face electrodes and the back surface electrodes being connected to the corresponding lands via solder, and in a mounting structure for the chip component, a distance between the pair of facing back surface electrodes is set to be shorter than a separation distance between the pair of lands, and portions of the back surface electrodes are disposed with protruding inwardly from the corresponding lands, respectively.

In the chip component mounting structure described above, portions of the back surface electrodes formed on the chip component are soldered with protruding inwardly from the corresponding lands, respectively. In this structure, the inner end of each of the back surface electrodes 3, which may be a starting point of peeling off, is not located directly above the inner end of each of the lands, and thus, even if the thermal stress caused by the thermal shock acts on the back surface electrodes, the back surface electrodes can be prevented from peeling off from the back surface of the insulating substrate.

In the structure described above, each of the back surface electrodes may be made of sintered silver. On the other hand, when each of the back surface electrodes is made of a resin material containing conductive particles formed in a thick film on the back surface of the insulating substrate, even if high-strength solder is used and thus the solder joint portion becomes rigid, the thermal stress caused by the thermal shock can be relaxed by the flexibility of the back surface electrodes.

In the case described above, when each of the back surface electrodes is provided with a thick portion of which a top portion faces toward each of the corresponding lands, the thick portion having a large film thickness improves the flexibility of each of the back surface electrodes, whereby the thermal stress caused by the thermal shock can be effectively relaxed.

In the structure described above, when the top portion of the thick portion formed on each of the back surface electrodes is located directly above an inner end of each of the corresponding lands, the thick portion is arranged at the position where the thermal stress caused by the thermal shock is likely to concentrate. This enables reliable prevention of peeling off of the back surface electrodes.

In the structure described above, each of the back surface electrodes may include a first electrode portion having a rectangular shape in plan view and located inwardly and away from an end face of the insulating substrate, and a plurality of second electrode portions separated and arranged on portions, respectively, in a short direction of the insulating substrate with a cutout portion, which is positioned between the end face of the insulating substrate and the first electrode portion, being interposed therebetween, and also the thick portion may be formed in the first electrode portion. This allows, using the surface tension of the resin paste which is a material of each of the back surface electrodes, the thick portion to be formed on each of the back surface electrodes by print-coating performed once.

### Advantageous Effects of Invention

According to the present invention, it is possible to provide a mounting structure for a chip component having high thermal shock resistance.

### BRIEF DESCRIPTION OF DRAWINGS

FIG. 1 is a cross-sectional view of a mounting structure for a chip resistor according to the first embodiment.

FIG. 2 is a cross-sectional view of amounting structure for a chip resistor according to the second embodiment.

FIG. 3 is a plan view of a chip resistor used in the mounting structure according to the second embodiment.

FIG. 4 is a cross-sectional view taken along the line IV-IV of FIG. 3.

FIG. 5 is a cross-sectional view taken along the line V-V of FIG. 3.

FIG. 6 is a diagram for explaining back surface electrodes provided in the chip resistor.

FIG. 7 Each of FIG. 7A to 7E is a cross-sectional view illustrating the production processes of the chip resistor.

FIG. 8 Each of FIG. 8F to 8G is a cross-sectional view illustrating the production processes of the chip resistor.

FIG. 9 illustrates a flowchart of the production processes of the chip resistor.

FIG. 10 illustrates a state in which the chip resistor according to the third embodiment is mounted.

### DESCRIPTION OF EMBODIMENTS

Hereinafter, an embodiment of the present invention will be described with reference to the drawings.

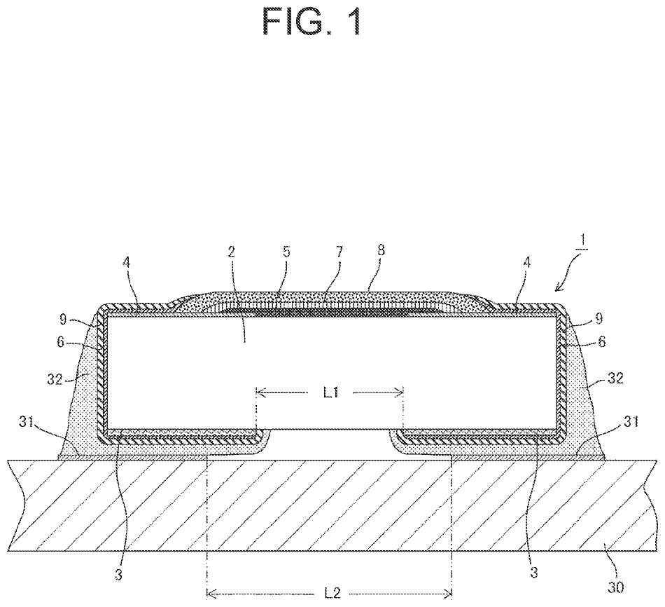

FIG. 1 is a cross-sectional view illustrating a mounting structure for a chip resistor according to the first embodiment, and as illustrated in FIG. 1, a chip resistor 1 is soldered to lands 31 of a circuit board 30. The circuit board 30 is made of a rigid board such as a glass epoxy board, and the lands 31 made of conductors such as copper foil are provided on the surface of the circuit board 30. The lands 31 are pads for solder connection of circuit patterns (not illustrated) provided on the circuit board 30, and external electrodes 9 of the chip resistor 1, which will be described later, are connected to the pair of lands 31 via solder 32, respectively.

A chip resistor 1 as a chip component includes a rectangular parallelepiped insulating substrate 2, a pair of back surface electrodes 3 that is provided at both ends, respectively, in the longitudinal direction on the back surface of the insulating substrate 2, a pair of top surface electrodes 4 that is provided at both ends, respectively, in the longitudinal direction on the top surface of the insulating substrate 2, a resistor 5 that is provided on the top surface of the insulating substrate 2 such that both ends thereof overlap with the pair of top surface electrodes 4, a pair of end face electrodes 6 having a U-shape in cross section, which is provided on both end faces, respectively, in the longitudinal direction of the insulating substrate 2 to bridge between the back surface electrodes 3 and the top surface electrodes 4, a protective layer having a double-layer structure (undercoat layer 7 and overcoat layer 8), which covers the resistor 5, and a pair of external electrodes 9 having a double-layer structure (Ni plating layer and Sn plating layer), which is formed by plating on the external surfaces of the end face electrodes 6 and back surface electrodes 3.

The insulating substrate 2 is a ceramic substrate containing alumina as a main component. The pair of back surface electrodes 3 is formed by screen-printing resin-paste containing conductive particles such as Ag, Ni, or carbon on the back surface of the large-sized substrate, and heating and curing the paste. The resistor 5, which is a function element, is obtained by screen-printing resistor paste, such as ruthenium oxide, on the top surface of the large-sized substrate and then drying and sintering the paste. Both ends of the resistor 5 in the longitudinal direction overlap with the pair of top surface electrodes 4, respectively. Although not illustrated, a trimming groove for adjusting a resistance value is formed in the resistor 5.

The pair of end face electrodes 6 is formed by sputtering nickel (Ni)/chromium (Cr) or the like, and the back surface electrodes 3 and the top surface electrodes 4, which are spaced apart from each other with the end faces of the insulating substrate 2 interposed therebetween, are electrically connected to each other by these end face electrodes 6. Note that each of the end face electrodes 6 extends beyond the boundary position between the top surface electrode 4 and the overcoat layer 8 to the side edge of the overcoat layer 8, and the flat top surface of the overcoat layer 8 is exposed without being covered by the end face electrodes 6.

The double-layered protective film is formed of the undercoat layer 7 and overcoat layer 8. The undercoat layer 7 is obtained by screen-printing glass paste and then drying and sintering the paste, and is formed so as to cover the resistor 5 before being provided with a trimming groove. The overcoat layer 8 is obtained by screen-printing epoxy resin paste and then heating and curing (baking) the paste, and is formed so as to cover the undercoat layer 7 after formation of the trimming groove.

Each of the pair of external electrodes 9 has a double-layer structure including a barrier layer and an external connection layer, and the barrier layer is an Ni plating layer formed by electroplating while the external connection layer is an Sn plating layer formed by electroplating. The external electrodes 9 are formed so as to cover the entire surfaces of the end face electrodes 6.

The chip resistor having the structure described above is, as illustrated in FIG. 1, mounted on lands 31 provided on a circuit board 30 with the back surface electrodes 3 facing downward, and is surface-mounted on the circuit board 30 by joining the pair of external electrodes 9 deposited on the end face electrodes 6 and back surface electrodes 3 to the corresponding lands 31 via the solder 32, respectively.

Here, the values of physical property, such as the linear expansion coefficient and Young's modulus, greatly vary between the insulating substrate 2 of the chip resistor 1 and the circuit board 30. This expands, contracts, and bends the circuit board 30, thereby causing the thermal stress due to the thermal shock. Under the thermal stress, the stress is concentrated between the inner end of the land 31 and the insulating substrate 2, and if an inner end of the back surface electrode 3 is located directly above the inner end of the land 31, the back surface electrode 3 peels off from the back surface of the insulating substrate 2 starting from the inner end of the back surface electrode 3. However, in the mounting structure for the chip resistor 1 according to the present embodiment, a separation distance L1 between the pair of back surface electrode 3 on the back surface of the insulating board 2 is set to be shorter than a separation distance L2 between the pair of lands 31, which makes the inner end of the back surface electrode 3 protrude inwardly from the corresponding land 31. Thus, in the mounting structure according to the present embodiment, the inner end of the back surface electrode 3 is disposed at a position shifted inwardly from the inner end of the land 31, and the inner end of the back surface electrode 3, which may be a starting point of peeling off, is not located directly above the inner end of the land 31. In this structure, even if the thermal stress caused by the thermal shock acts on the back surface electrodes 3, the back surface electrodes 3 can be prevented from peeling off from the back surface of the insulating substrate 2.

As described above, in the mounting structure for the chip resistor 1 according to the first embodiment, the separation distance L1 between the pair of back surface electrode 3 on the back surface of the insulating substrate 2 is set to be shorter than the separation distance L2 between the pair of lands 31, and the inner end of the back surface electrode 3 is soldered with protruding inwardly from the corresponding land 31. In this structure, the face of the back surface electrode 3 is located directly above the inner end of the land 31, but the inner end of the back surface electrode 3, which may be a starting point of peeling off, is not located directly above the inner end of the land 31. Thus, even if the thermal stress caused by the thermal shock acts on the back surface electrodes 3, the back surface electrodes 3 can be prevented from being peeled off from the back surface of the insulating substrate 2.

Moreover, each of the back surface electrodes 3 of the chip resistor 1 is formed of a resin material containing conductive particles such as carbon. This allows the thermal stress caused by the thermal shock to be relaxed by the flexibility of the back surface electrodes 3 even when the solder 32 is high-strength solder having a large Young's modulus and the solder joint portion becomes rigid, thereby preventing the solder cracks caused by the thermal stress.

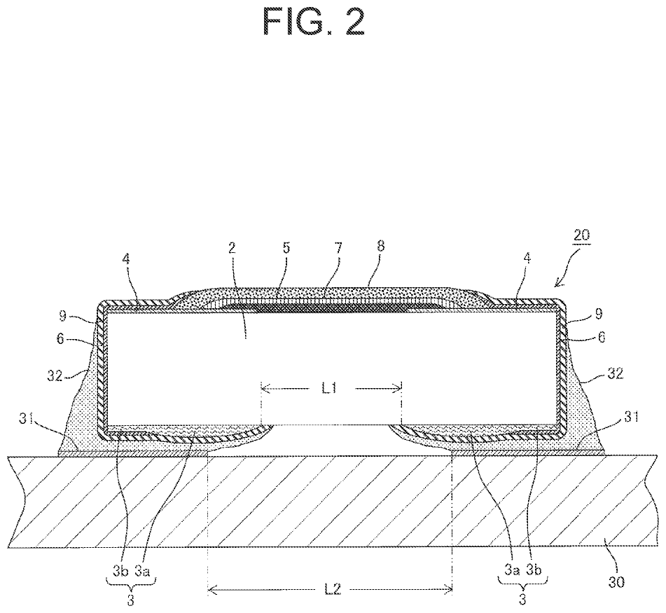

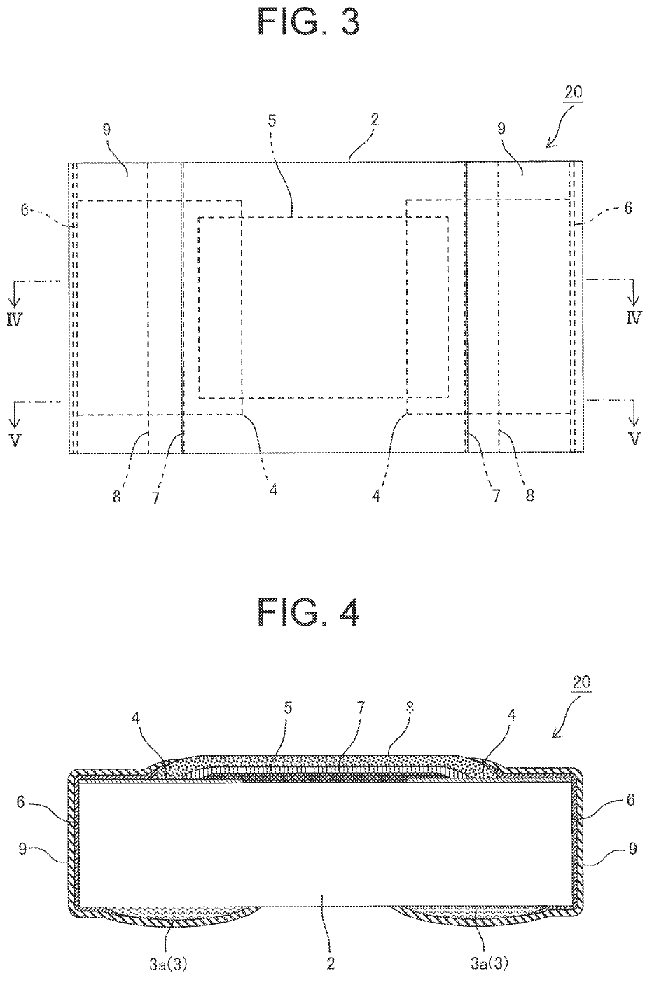

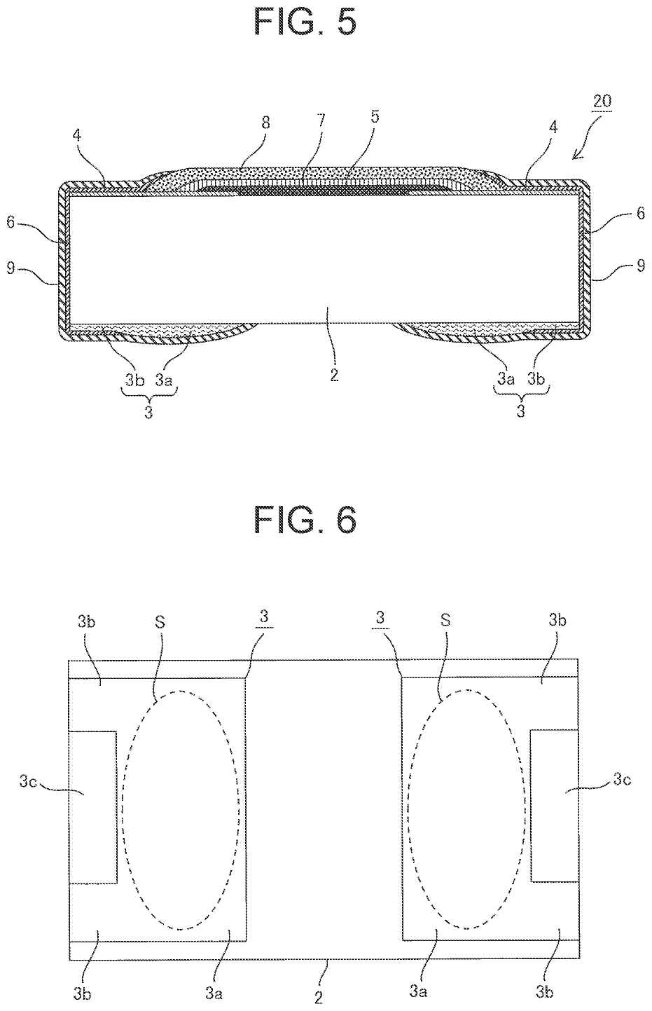

FIG. 2 is a cross-sectional view illustrating a mounting structure for a chip resistor according to the second embodiment, FIG. 3 is a plan view of a chip resistor 20 used in the mounting structure according to the second embodiment, FIG. 4 is a cross-sectional view taken along the line IV-IV of FIG. 3, and FIG. 5 is a cross-sectional view taken along the line V-V of FIG. 3. In these drawings, portions corresponding to those illustrated in FIG. 1 are provided with the same reference signs.

The mounting structure according to the second embodiment differs from the mounting structure according to the first embodiment in the structure of the back surface electrodes 3 of the chip resistor 20 to be mounted on the circuit board 30 while the others are basically the same. That is, the chip resistor 20 includes a rectangular parallelepiped insulating substrate 2, a pair of back surface electrodes 3 that is provided at both ends, respectively, in the longitudinal direction on the back surface of the insulating substrate 2, a pair of top surface electrodes 4 that is provided at both ends, respectively, in the longitudinal direction on the top surface of the insulating substrate 2, a resistor 5 that is provided on the top surface of the insulating substrate 2 such that both ends thereof overlap with the pair of top surface electrodes 4, a pair of end face electrodes 6 having a U-shape in cross section, which is provided on both end faces, respectively, in the longitudinal direction of the insulating substrate 2 to bridge between the back surface electrodes 3 and the top surface electrodes 4, a protective layer having a double-layer structure (undercoat layer 7 and overcoat layer 8), which covers the resistor 5, and a pair of external electrodes 9 having a double-layer structure (Ni plating layer and Sn plating layer), which is formed by plating on the external surfaces of the end face electrodes 6 and back surface electrodes 3.

In the chip resistor 20 having the structure described above, portions other than the back surface electrodes 3 are the same as those of the chip resistor 1 according to the first embodiment. Thus, in the following, the back surface electrodes 3 will be described in detail while the repetitive explanation for the common portions is omitted.

FIG. 6 is a diagram for explaining the back surface electrodes 3 formed on the back surface of the insulating substrate 2, in which the end face electrodes 6 and the external electrodes 9 are not illustrated in order to show the shape of the back surface electrodes 3 easily. As illustrated in FIG. 6, each of the back surface electrodes 3 is formed to have a channel shape (U-shape) in plan view, and includes the first electrode portion 3a and the two second electrode portions 3b. The first electrode portion 3a has a rectangular shape in plan view, and is located inwardly and away from the end face of the insulating substrate 2. The second electrode portions 3b are separated arranged on two portions, respectively, which are separated in the short direction of the insulating substrate 2 with a cutout portion 3c, which is located between the end face of the insulating substrate 2 and the first electrode portion 3a, being interposed therebetween. The cutout portion 3c is a non-coated portion on which the resin material of the back surface electrodes 3 is not printed, and the first electrode portion 3a and the two second electrode portions 3b are consecutively formed in a U-shape so as to surround the cutout portion 3c.

The cross-sectional shape of the portion surrounded by a dotted line S in the first electrode portion 3a is arcuate (semi-cylindrical shape), in which the thickness thereof in the height direction gradually increases from both ends to the center along the longitudinal direction of the insulating substrate 2. Forming the first electrode portion 3a into the arcuate shape as described above makes the first electrode portion 3a a thick portion of which the film thickness is more than that of the second electrode portions 3b. The first electrode portion 3a having the arcuate shape as described above can be easily formed by applying the resin paste, which is the material of the back surface electrodes 3, once and causing the surface tension.

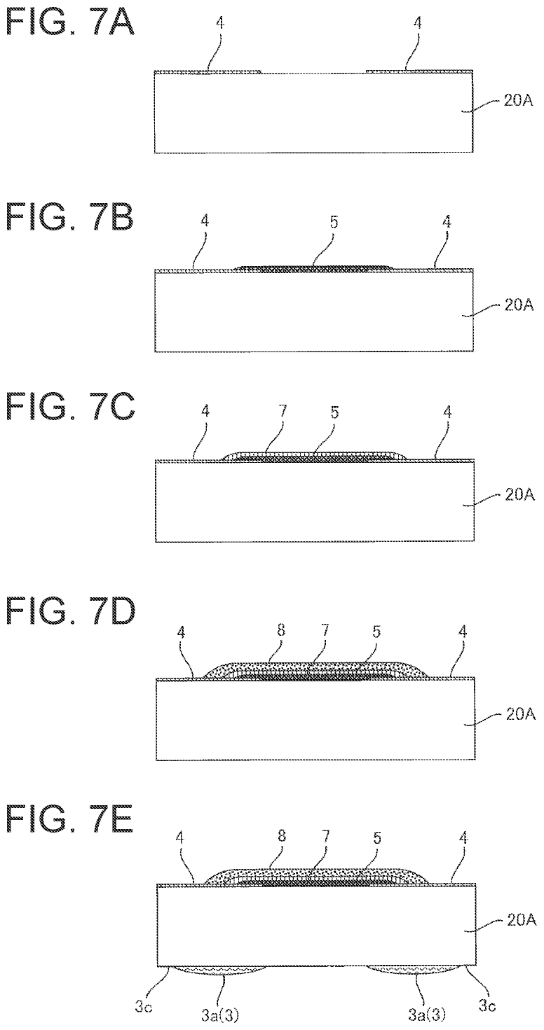

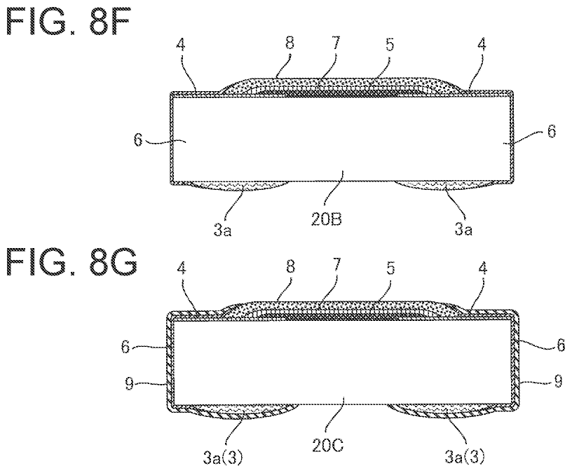

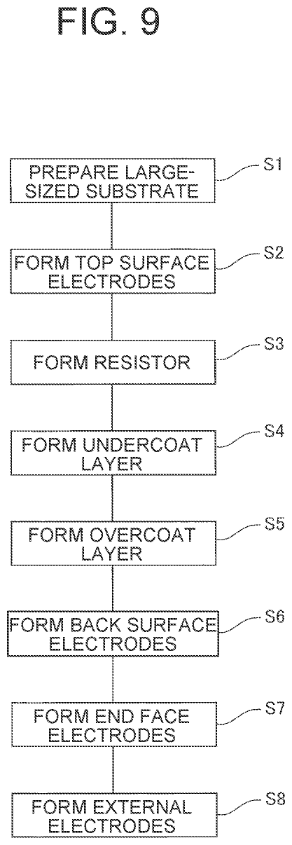

Next, a method of producing the chip resistor 20 having the structure described above will be described with reference to FIG. 7A to 7E to FIG. 9. FIG. 7A to 7E and FIG. 8F to 8G are cross-sectional views illustrating the processes of producing the chip resistor 20, and FIG. 9 illustrates a flowchart of the production processes of the chip resistor 20.

Firstly, as illustrated in step S1 of FIG. 9, a large-sized and sheet-shaped substrate 20A, from which a plurality of insulating substrates 2 is to be obtained, is prepared (large-sized substrate preparing process). The large-sized substrate 20A is provided with primary division grooves and secondary division grooves (both not illustrated) which extend to form a grid pattern, and each of the squares partitioned by these division grooves serves as one chip-forming area. Each of FIG. 7A to 7E and FIG. 8F to 8G illustrates the cross-sectional view of one chip-forming area, however, practically, processes to be described below are carried out collectively for the large-sized substrate 20A corresponding to a plurality of chip-forming areas.

That is, in step S2 of FIG. 9, as illustrated in FIG. 7(a), for forming, on the top surface of the large-sized substrate 20A, the top surface electrodes 4 facing each other across the chip-forming areas, the Ag paste is screen-printed in an area sandwiched between the secondary division grooves on the top surface of the large-sized substrate 20A so as to extend across each of the primary division grooves and then dried and sintered (top surface electrode forming process).

Next, in step S3 of FIG. 9, as illustrated in FIG. 7(b), for forming the resistor 5 that extends between the pair of top surface electrodes 4, the resistor paste such as ruthenium oxide is screen-printed on the top surface of the large-sized substrate 20A and then dried and sintered (resistor forming process).

Next, in step S4 of FIG. 9, as illustrated in FIG. 7(c), for forming the undercoat layer 7 that covers the resistor 5, the glass paste is screen-printed and then dried and sintered (undercoat forming process). Then, a trimming groove (not illustrated) is formed in the resistor 5 from above the undercoat layer 7 to adjust a resistance value.

Next, in step S5 of FIG. 9, as illustrated in FIG. 7(d), for forming the overcoat layer 8 that covers portions of the top surface electrodes 4 and the entire of the resistor 5, the epoxy resin paste is screen-printed from above the undercoat layer 7 and then heated and cured (overcoat forming process). The protective layer having a double-layered structure for covering the resistor 5 is formed of these undercoat layer 7 and overcoat layer 8.

Next, in step S6 of FIG. 9, as illustrated in FIG. 7(e), for forming the back surface electrodes 3 facing each other with the primary division grooves therebetween at each chip forming area on the back surface of the large-sized substrate 20A, the resin paste containing conductive particles (for example, Ag) is screen-printed so as to extend across the primary division grooves in the region sandwiched between the secondary division grooves on the back surface of the large-sized substrate 20A, and then is heated and cured (back surface electrode forming step).

As illustrated in FIG. 6, each of the back surface electrodes 3 includes the first electrode portion 3a located inwardly at the chip forming region and away from the primary division groove, and the two second electrode portions 3b separated and arranged along the secondary division groove with the cutout portion 3c, which is located between the primary division groove and the first electrode portion 3a, being interposed therebetween. The back surface electrodes 3, each of which has a channel shape (U-shape) in plan view, are formed at both ends, respectively, in the longitudinal direction of the chip forming region. That is, the cutout portion 3c is a non-coating portion on which the resin paste is not printed, and the two second electrode portions 3b extending in parallel to each other and the first electrode portion 3a are formed consecutively in a U-shape so as to surround the cutout portion 3c. In the back surface electrode 3 having the shape as described above, even with a single-layer structure obtained by coating the resin paste only once, the maximum height of the first electrode portion 3a is more than the maximum height of the second electrode portions 3b due to the surface tension of the resin paste, which enables a thick portion, of which the cross-sectional shape is arcuate, to be easily formed on the first electrode portion 3a.

The processes described above are carried out collectively for the large-sized substrate 20A. In the next process, the large-sized substrate 20A is divided by primary breaking (primary division) along the primary division grooves to obtain a strip-shaped substrate 20B. The cutout portion 3c, which is a portion where the resin paste is not applied, is formed between both the second electrode portions 3b of the back surface electrode 3, and this cutout portion 3c is located on the first division groove, which enhances the performance of breaking in the primary breaking of the large-sized substrate 20A.

Thereafter, in step S7 of FIG. 9, as illustrated in FIG. 8(f), for forming, on both end faces of the strip-shaped substrate 20B, the end face electrodes 6 that electrically connect between the top surface electrodes 4 and the back surface electrodes 3, Ni—Cr is applied on the divided faces of the strip-shaped substrate 20B by sputtering (end face electrode forming process). Each of the end face electrodes 6 covers a portion of the back surface of the strip-shaped substrate 20B which is exposed from the cutout portion 3c, and also covers both the second electrode portions 3b of the back surface electrode 3 excluding the first electrode portion 3a.

Next, the strip-shaped substrate 20B is divided by secondary breaking (secondary division) along the secondary division grooves to obtain a single chip 20C having the size equivalent to that of the chip resistor 20.

In the final process, as illustrated in FIG. 8(g), for forming the external electrodes 9 including an Ni plating layer and Sn plating layer on the entire surfaces of the end face electrodes 6 and the surfaces of the first electrode portions 3a, the single chip 20C obtained as a piece is electroplated (external electrode forming process). Thus, the chip resistor 20 as illustrated in FIG. 3 to FIG. 5 is obtained.

The chip resistor 20 thus produced is, as illustrated in FIG. 2, mounted on the lands 31 provided on the circuit board 30 with the back surface electrodes 3 facing downward, and is surface-mounted by joining the pair of external electrodes 9 to the corresponding lands 31, respectively.

In the mounting structure for the chip resistor 20 according to the second embodiment, in the same manner as the first embodiment, the separation distance L1 between the pair of back surface electrodes 3 on the back surface of the insulating substrate 2 is set to be shorter than the separation distance L2 between the pair of lands 31, and the inner end of each of the back surface electrodes 3 protrudes inwardly from the corresponding land 31. Thus, in the mounting structure according to the present embodiment, the inner end of the back surface electrode 3 is disposed at a position shifted inwardly from the inner end of the land 31, and the inner end of the back surface electrode 3, which may be a starting point of peeling off, is not located directly above the inner end of the land 31. In this structure, even if the thermal stress caused by the thermal shock acts on the back surface electrodes 3, the back surface electrodes 3 can be prevented from peeling off from the back surface of the insulating substrate 2.

Furthermore, in the mounting structure for the chip resistor 20 according to the second embodiment, the first electrode portion 3a (thick portion) having an arcuate shape in cross-section, of which the top portion faces toward the land 31, is formed on each of the back surface electrodes 3 of the chip resistor 20. In this structure, the first electrode portion 3a (thick portion) having a large film thickness improves the flexibility of each of the back surface electrodes 3, whereby the thermal stress caused by the thermal shock and acting on the back surface electrodes 3 can be effectively relaxed. Moreover, the top portion of the first electrode portion 3a is made positioned directly above the inner end of the land 31 in which the thermal stress caused by the thermal shock is likely to concentrate, which allows the thermal stress caused by the thermal shock to be efficiently absorbed by the thick portion of the first electrode portion 3a. This enables reliable prevention of peeling off of the back surface electrodes 3.

Still further, in the mounting structure for the chip resistor 20 according to the second embodiment, each of the back surface electrodes 3 of the chip resistor 20 to be mounted on the circuit board 30 includes the first electrode portion 3a having a rectangular shape in plan view and located inwardly and away from the end face of the insulating substrate 2, and the two second electrode portions 3b separated and arranged on two portions, respectively, in the short direction of the insulating substrate 2 with the cutout portion 3c, which is positioned between the end face of the insulating substrate 2 and the first electrode portion 3a, being interposed therebetween, and thus each of the back surface electrodes is formed into a channel shape (U-shape) as a whole. This allows, using the surface tension of the resin paste which is a material of the back surface electrode 3, the first electrode portion 3a formed to have thickness to be provided on the back surface electrode 3 by print-coating performed once.

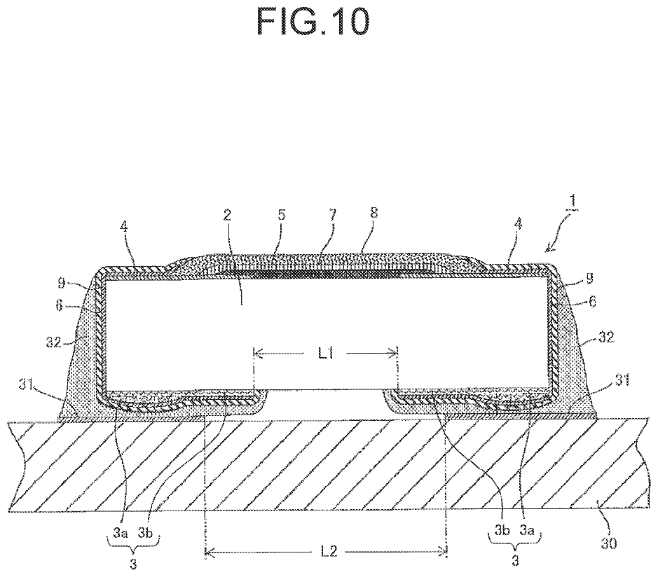

In the second embodiment, a thick portion (first electrode portion 3a) is formed on the side of the inner end of the back surface electrode 3, and the top portion of the thick portion is made positioned directly above the inner end of the land 31. However, a position where the thick portion is to be formed within the back surface electrode 3 is not limited to the inner end side. For example, as in the mounting structure for the chip resistor according to a third embodiment illustrated in FIG. 10, the second electrode portion 3b of which the film thickness is thin may be formed inwardly and away from the end face of the insulating substrate 2 while forming the first electrode portion 3a having a thick portion on the side of the outer end of the back surface electrode 3, or the thick portion (first electrode portion 3a) may be formed near the center portion of the back surface electrode 3.

In each of the embodiments described above, the chip resistor having a resistor as a function element, to which the present invention has been applied, has been described. On the other hand, the present invention is also applicable to a function element other than the resistor, for example, a chip component having an inductor, a capacitor, or the like.

### REFERENCE SIGNS LIST

1, 20 chip resistor (chip component)
2 insulating substrate
3 back surface electrode
3a first electrode portion (thick portion)
3b second electrode portion
3c cutout portion
4 top surface electrode
5 resistor (function element)
6 end face electrode
7 undercoat layer
8 overcoat layer
9 external electrode
20A large-sized substrate
20B strip-shaped substrate
20C single chip
30 circuit board
31 land
32 solder

1. A chip component mounting structure, comprising a chip component being provided with:
a pair of back surface electrodes formed at both ends, respectively, in a longitudinal direction of a back surface of a rectangular parallelepiped insulating substrate; and
end surface electrodes formed at the both ends, respectively, in the longitudinal direction of the insulating substrate and connected to the back surface electrodes, respectively,
the chip component being mounted on a pair of lands provided on a circuit board with the pair of back surface electrodes facing downward, and
the end face electrodes and the back surface electrodes being connected to the corresponding lands via solder, wherein
a distance between the pair of facing back surface electrodes is set to be shorter than a separation distance between the pair of lands, and portions of the back surface electrodes are disposed with protruding inwardly from the corresponding lands, respectively.

2. The chip component mounting structure according to claim 1, wherein
each of the back surface electrodes is made of a resin material containing conductive particles formed in a thick film on the back surface of the insulating substrate.

3. The chip component mounting structure according to claim 2, wherein
each of the back surface electrodes is provided with a thick portion of which a top portion faces toward each of the corresponding lands.

4. The chip component mounting structure according to claim 3, wherein
the top portion of the thick portion is located directly above an inner end of each of the corresponding lands.

5. The chip component mounting structure component according to claim 4, wherein
each of the back surface electrodes includes a first electrode portion having a rectangular shape in plan view and located inwardly and away from an end face of the insulating substrate, and a plurality of second electrode portions separated and arranged on portions, respectively, in a short direction of the insulating substrate with a cutout portion, which is positioned between the end face of the insulating substrate and the first electrode portion, being interposed therebetween, and
the thick portion is formed in the first electrode portion.
